(19) United States
(12) Patent Application Publication
(10) Pub. No.: US 2024/0062332 A1
(43) Pub. Date: Feb. 22, 2024

(54) SYSTEM AND METHOD FOR IMPROVING SHARPNESS OF MAGNETIC RESONANCE IMAGES USING A DEEP LEARNING NEURAL NETWORK

(71) Applicant: Beth Israel Deaconess Medical Center, Inc., Boston, MA (US)

(72) Inventors: Siyeop Yoon, Boston, MA (US); Reza Nezafat, Newton, MA (US)

(21) Appl. No.: 17/887,096

(22) Filed: Aug. 12, 2022

(51) Int. Cl. G06T 3/40; G06T 5/00; G06T 5/10; G01R 33/48

(52) U.S. Cl. CPC G06T 3/4046; G06T 5/003; G06T 5/10; G01R 33/4818; G06T 2207/20081; G06T 2207/20084; G06T 2207/30048

(57) ABSTRACT

A method for generating a magnetic resonance (MR) image of a subject includes receiving an MR image of the subject reconstructed from undersampled MR data of the subject and providing the low resolution MR image of the subject to an image sharpness neural network. The image sharpness neural network can be implemented without an upsampling layer. The image sharpness neural network may be trained using a set of loss functions including an L₁ Fast Fourier Transform (FFT) loss function. The method may further include generating an enhanced resolution MR image of the subject with increased sharpness based on the MR image of the subject using the image sharpness neural network.

### STATEMENT REGARDING FEDERALLY SPONSORED RESEARCH

This technology was made with government support under Grant No. HL158077 awarded by the National Institutes of Health. The government has certain rights in the technology.

### FIELD

The present disclosure relates generally to magnetic resonance imaging and, more particularly, to a system and method for accelerated MR imaging with improved sharpness using a deep learning neural network, for example, a generative adversarial network (GAN), for image reconstruction.

### BACKGROUND

Magnetic resonance imaging (MM) is recognized as a powerful non-invasive imaging modality for evaluation of function, morphology, and perfusion. Despite the significant growth in the clinical use of MRI, the imaging protocol remains long. In addition, long scan time limits spatial and temporal resolution and could degrade image quality. Parallel imaging (e.g., SENSE or GRAPPA) and compressed sensing (CS) techniques may be used to reduce scan time. Parallel imaging typically allows 2- to 3-fold acceleration in most routine MRI sequences. Clinical application of CS has been limited to acceleration between 2-7. While parallel imaging and CS techniques have shortened the imaging time, these acceleration techniques have limited acceleration factors. For example, for parallel imaging, the rate of acceleration is limited depending on the hardware specifications of the scanner. In addition, despite recent advances in CS to accelerate MR imaging, there are still limitations for wide clinical adoption in MR imaging. CS reconstruction time remains long, even with a state-of-the-art hardware system, is only available for specific sequences (e.g., cardiac cine), and often uses spatial-temporal redundancy resulting in considerable temporal blurring.

To further accelerate MM acquisition and reconstruction, deep learning (DL) methods have recently been used. In particular, DL super-resolution techniques began to be applied to MRI acceleration with the success of single image super-resolution. DL super-resolution techniques accelerate MRI by reconstructing a high spatial resolution image from a low spatial resolution image to reduce k-space data acquisition. However, the current techniques were trained using synthesized training datasets in the image domain, resulting in a discrepancy between training and prospective acquisition. The upsampling layer in network architectures can coerce a fixed acceleration factor and limited imaging matrix size. In addition, current DL-based techniques can require imaging sequence-specific training datasets. The generalizability of DL techniques for different sequences, slice orientations, and ease of inline integration into the standard clinical system remains challenging.

It would be desirable to provide a system and method for accelerated MR imaging that overcomes the challenges of prior parallel imaging, CS and DL-based techniques.

### SUMMARY

In accordance with an embodiment, a method for generating a magnetic resonance (MR) image of a subject includes receiving an MR image of the subject reconstructed from undersampled MR data of the subject and providing the MR image of the subject to an image sharpness neural network without an upsampling layer. The image sharpness neural network may be trained using a set of loss functions including an L₁ Fast Fourier Transform (FFT) loss function. The method may further include generating an enhanced resolution MR image of the subject with increased sharpness based on the MR image of the subject using the image sharpness neural network.

In accordance with another embodiment, a system for generating a magnetic resonance (MR) image of a subject included an input for receiving an MR image of the subject reconstructed from undersampled MR data of the subject and an image sharpness neural network without an upsampling layer and coupled to the input. The image sharpness neural network may be trained using a set of loss functions including an L₁ Fast Fourier Transform (FFT) loss function. The image sharpness neural network may be configured to generate an enhanced resolution MR image of the subject with increased sharpness based on the MR image of the subject.

### BRIEF DESCRIPTION OF THE DRAWINGS

The present disclosure will hereafter be described with reference to the accompanying drawings, wherein like reference numerals denote like elements.

FIG. 1 is a block diagram of an example magnetic resonance imaging (MM) system in accordance with an embodiment;

FIG. 2 is a block diagram of a method for generating magnetic resonance images using an image sharpness neural network in accordance with an embodiment;

FIG. 3 illustrate a method for generating magnetic resonance images using an image sharpness neural network in accordance with an embodiment;

FIG. 4 illustrates a generator network architecture for the image sharpness neural network of FIG. 2 in accordance with an embodiment;

FIG. 5 illustrates a discriminator network architecture for the image sharpness neural network of FIG. 2 in accordance with an embodiment; and

FIG. 6 is a block diagram of an example computer system in accordance with an embodiment.

### DETAILED DESCRIPTION

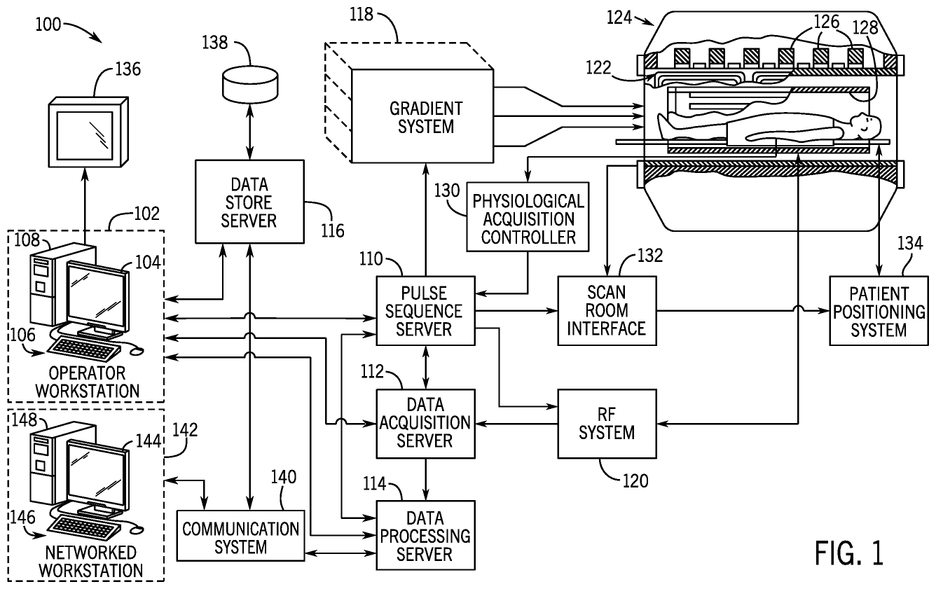

Referring now to FIG. 1, the disclosed systems and methods may be implemented using or designed to accompany a magnetic resonance imaging (“MM”) system 100, such as is illustrated in FIG. 1. The MM system 100 includes an operator workstation 102, which will typically include a display 104, one or more input devices 106 (such as a keyboard and mouse or the like), and a processor 108. The processor 108 may include a commercially available programmable machine running a commercially available operating system. The operator workstation 102 provides the operator interface that enables scan prescriptions to be entered into the MRI system 100. In general, the operator workstation 102 may be coupled to multiple servers, including a pulse sequence server 110; a data acquisition server 112; a data processing server 114; and a data store server 116. The operator workstation 102 and each server 110, 112, 114, and 116 are connected to communicate with each other. For example, the servers 110, 112, 114, and 116 may be connected via a communication system 140, which may include any suitable network connection, whether wired, wireless, or a combination of both. As an example, the communication system 140 may include both proprietary or dedicated networks, as well as open networks, such as the internet.

The pulse sequence server 110 functions in response to instructions downloaded from the operator workstation 102 to operate a gradient system 118 and a radiofrequency (“RF”) system 120. Gradient waveforms to perform the prescribed scan are produced and applied to the gradient system 118, which excites gradient coils in an assembly 122 to produce the magnetic field gradients Gₓ, G_{y}, G_{z} used for position encoding magnetic resonance signals. The gradient coil assembly 122 forms part of a magnet assembly 124 that includes a polarizing magnet 126 and a whole-body RF coil 128.

RF waveforms are applied by the RF system 120 to the RF coil 128, or a separate local coil (not shown in FIG. 1), in order to perform the prescribed magnetic resonance pulse sequence. Responsive magnetic resonance signals detected by the RF coil 128, or a separate local coil, are received by the RF system 120, where they are amplified, demodulated, filtered, and digitized under direction of commands produced by the pulse sequence server 110. The RF system 120 includes an RF transmitter for producing a wide variety of RF pulses used in MM pulse sequences. The RF transmitter is responsive to the scan prescription and direction from the pulse sequence server 110 to produce RF pulses of the desired frequency, phase, and pulse amplitude waveform. The generated RF pulses may be applied to the whole-body RF coil 128 or to one or more local coils or coil arrays.

The RF system 120 also includes one or more RF receiver channels. Each RF receiver channel includes an RF preamplifier that amplifies the magnetic resonance signal received by the coil 128 to which it is connected, and a detector that detects and digitizes the/and Q quadrature components of the received magnetic resonance signal. The magnitude of the received magnetic resonance signal may, therefore, be determined at any sampled point by the square root of the sum of the squares of the/and Q components:

M=\sqrt{I²+Q²} (1)

and the phase of the received magnetic resonance signal may also be determined according to the following relationship:

$$φ = {tan}^{- 1} ( \frac{Q}{I} ) \qquad ( 2 )$$

The pulse sequence server 110 also optionally receives patient data from a physiological acquisition controller 130. By way of example, the physiological acquisition controller 130 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 110 to synchronize, or “gate,” the performance of the scan with the subject's heart beat or respiration.

The pulse sequence server 110 also connects to a scan room interface circuit 132 that receives signals from various sensors associated with the condition of the patient and the magnet system. It is also through the scan room interface circuit 132 that a patient positioning system 134 receives commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, such that no data is lost by data overrun. In some scans, the data acquisition server 112 does little more than pass the acquired magnetic resonance data to the data processor server 114. However, in scans that require information derived from acquired magnetic resonance data to control the further performance of the scan, the data acquisition server 112 is programmed to produce such information and convey it to the pulse sequence server 110. For example, during prescans, magnetic resonance data is acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also be employed to process magnetic resonance signals used to detect the arrival of a contrast agent in a magnetic resonance angiography (“MRA”) scan. By way of example, the data acquisition server 112 acquires magnetic resonance data and processes it in real-time to produce information that is used to control the scan.

The data processing server 114 receives magnetic resonance data from the data acquisition server 112 and processes it in accordance with instructions downloaded from the operator workstation 102. Such processing may, for example, include one or more of the following: reconstructing two-dimensional or three-dimensional images by performing a Fourier transformation of raw k-space data; performing other image reconstruction techniques, such as iterative or back-projection reconstruction techniques; applying filters to raw k-space data or to reconstructed images; generating functional magnetic resonance images; calculating motion or flow images; and so on.

Images reconstructed by the data processing server 114 are conveyed back to the operator workstation 102. Images may be output to operator display 112 or a display 136 that is located near the magnet assembly 124 for use by attending clinician. Batch mode images or selected real time images are stored in a host database on disc storage 138. When such images have been reconstructed and transferred to storage, the data processing server 114 notifies the data store server 116 on the operator workstation 102. The operator workstation 102 may be used by an operator to archive the images, produce films, or send the images via a network to other facilities.

The MM system 100 may also include one or more networked workstations 142. By way of example, a networked workstation 142 may include a display 144, one or more input devices 146 (such as a keyboard and mouse or the like), and a processor 148. The networked workstation 142 may be located within the same facility as the operator workstation 102, or in a different facility, such as a different healthcare institution or clinic. The networked workstation 142 may include a mobile device, including phones or tablets.

The networked workstation 142, whether within the same facility or in a different facility as the operator workstation 102, may gain remote access to the data processing server 114 or data store server 116 via the communication system 140. Accordingly, multiple networked workstations 142 may have access to the data processing server 114 and the data store server 116. In this manner, magnetic resonance data, reconstructed images, or other data may exchange between the data processing server 114 or the data store server 116 and the networked workstations 142, such that the data or images may be remotely processed by a networked workstation 142. This data may be exchanged in any suitable format, such as in accordance with the transmission control protocol (“TCP”), the internet protocol (“IP”), or other known or suitable protocols.

The present disclosure describes a system and method for generating a magnetic resonance (MR) image using an image sharpness neural network. In some embodiments, the image sharpness neural network is a deep learning neural network, for example, generative adversarial network (GAN), that includes a generator network and a discriminator network. The disclosed system and method can provide an MR image acquisition and reconstruction pipeline and can include a deep learning-based image reconstruction technique or framework (e.g., utilizing a GAN) that can be used to achieve faster imaging (e.g., accelerated MM). In some embodiments, the GAN can be combined with conventional accelerated methods of MR imaging (e.g., parallel imaging, compressed sensing, partial Fourier, sliding window, MR fingerprinting, multi-tasking, or other known acceleration techniques). In some embodiments, the deep learning-based image reconstruction technique can be implemented using a modified enhanced super-resolution generative adversarial neural network (mESRGAN) model as described herein.

In some embodiments, the image sharpness neural network (e.g., a GAN such as the mESRGAN described herein) may be configured to generate an enhanced resolution (or high resolution) MR image with increased sharpness. In some embodiments, the image sharpness neural network does not include an upsampling layer and may be trained using a set of loss functions that includes an L₁ Fast Fourier Transform loss function. Without an upsampling layer, the image sharpness neural network (e.g., a GAN) may produce an enhanced resolution MR image with the same or larger matrix size as an input MR image, for example, a low resolution MR image, and may be used to accelerate with a flexible selection of acceleration factors. In some embodiments, the MR image input to the image sharpness neural network may be an accelerated (e.g., with parallel imaging or compressed sensing) MR image with reduced phase encode lines. For example, in some embodiments, the input MR image may be generated using the low-frequency region of k-space or the central (or inner) region of k-space. Based on the input MR image (e.g., a low resolution MR image), the image sharpness neural network may be configured to generate an enhanced resolution MR image with, for example, improved sharpness. Accordingly, the image sharpness neural network may be configured to recover lost image sharpness from the accelerated (undersampled) data acquisition for the MR image input to the image sharpness neural network. In some embodiments, the MR image of the subject (e.g., a low resolution MR image) may be acquired using known MR imaging acquisition techniques such as cine (e.g., ECG-segmented cine, real-time cine at rest or physiological exercise stress), late gadolinium enhancement (LGE), quantitative imaging such as T1, T2, T2*, myocardial perfusion, or cardiac diffusion.

In some embodiments, the image sharpness neural network (e.g., a GAN such as the mESRGAN described herein) may enable a 4- to 15-fold acceleration of MRI, enabling, for example, reduced scan time and increased spatial or temporal resolution. In some embodiments, the image sharpness neural network used in the disclosed system and method can be generalized for different imaging planes, cardiac rhythm, respiratory motion, imaging parameters/acceleration factors, and can be combined with different acceleration techniques such as, for example, parallel imaging, compressed sensing, partial Fourier, sliding window, MR fingerprinting, multi-tasking, or other known acceleration techniques.

In some embodiments, the accelerated MR images generated using the disclosed system and method may enable, for example, the evaluation of cardiac function for a subject at rest and post-exercise. For example, in some embodiments, the disclosed system and method for generating an MR image using an image sharpness neural network can enable real time cine allowing evaluation of, for example, LV (left ventricular) function at rest and post-exercise. In some embodiments, the disclosed system and method for generating an MR image using an image sharpness neural network can be used to reduce the scan time of LGE without compromising imaging quality or artifacts, reducing the breath-hold burden on patients.

In some embodiments, the disclosed system and method for generating an MR image of a subject using an image sharpness neural network may be deployed on an MM system or scanner (e.g., MRI system 100 shown in FIG. 1) for prospective MR data collection and inline image reconstruction. For example, in some embodiments, the image sharpness neural network (e.g., a GAN) may be integrated into the clinical workflow on an MRI system for acquisition and reconstruction of MR images. The inline implementation of the GAN (e.g., a GAN such as the mESRGAN disclosed herein) can allow for rapid deployment of the disclosed system and method in clinical workflow and prospective accelerated image acquisition and reconstruction. In some embodiments, both the input MR image (e.g., a low resolution MR image) and the output enhanced resolution MR image with increased sharpness may be available (e.g., displayed) immediately to a user allowing the user to review the images in real time to, for example, determine if a follow up scan is needed. Availability of a low resolution input MR image may also provide some level of confidence to the user to investigate if artifacts or hallucination that could appear in the generated enhanced resolution MR image due to use of a GAN exists on the input low resolution MR image.

Advantageously, the disclosed image sharpness neural network (e.g., the mESRGAN described herein) does not require any specific sampling scheme or sequence modification. Accordingly, the disclosed image sharpness neural network (e.g., the disclosed mESRGAN) may be readily integrated into any available clinical pulse sequence without any pulse sequence programming and modifications. In some embodiments, the disclosed image sharpness neural network may be trained using retrospectively collected data. In some embodiments, the training dataset for the image sharpness neural network (e.g., the mESRGAN described herein) may include pairs of low resolution and high resolution images.

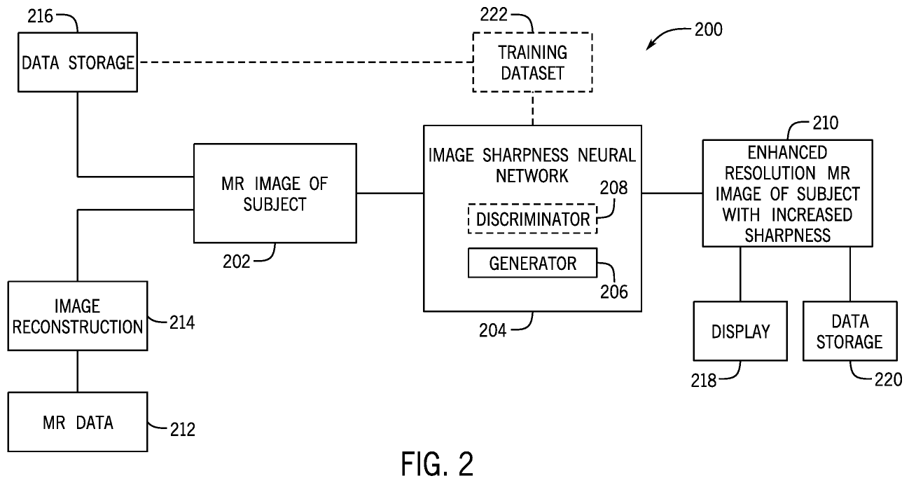

FIG. 2 is a block diagram of a system for generating a magnetic resonance (MR) image using an image sharpness neural network in accordance with an embodiment. The system 200 can include an input 202 including an MR image of the subject (e.g., a low resolution MR image), an image sharpness neural network (e.g., a deep learning neural network such as, for example, a generative adversarial network (GAN)) 204 including a generator (or generative) network 206 and a discriminator (or discriminative) network 208, an output 210 including an enhanced resolution MR image of the subject with increased sharpness, an imaging reconstruction module 214, data storage 216, a display 218 and data storage 220. The system 200 may be configured to provide an accelerated MR image (e.g., cardiac images) acquisition and reconstruction pipeline. In some embodiments, the input MR image 202 of the subject may be a cardiac MR image. The input MR image 202 may be acquired using an MM system such as, for example, MM system 100 shown in FIG. 1 using known MR imaging acquisition techniques such as, for example, cine, LGE, quantitative imaging such as T1, T2, T2*, myocardial perfusion, or cardiac diffusion.

In some embodiments, the input MR image 202 may be reconstructed from undersampled (or accelerated) MR data (e.g., MR data 212 as discussed further below). For example, during acquisition of the MR data using an MM system, k-space may be undersampled using either a uniform or non-uniform undersampling scheme. In some embodiments, the undersampled k-space data is collected or acquired from the central (or inner) region of k-space. In some embodiments, the undersampled k-space data can include a reduced (e.g., partially acquired) number of phase encode lines. In some embodiments, the phase encode lines may be acquired only in the central region of k-space (i.e., outer k-space lines are not collected). An acceleration technique may be used to estimate (or interpolate) missing k-space lines in the central region of k-space, for example, a parallel imaging technique (e.g., GRAPPA or SENSE) for uniform undersampling schemes and a compressed sensing technique for non-uniform undersampling schemes. In some embodiments, the reconstructed central region of k-space may then be zero-padded (e.g., an out region of k-space) to create a zero-padded k-space. The MR image 202 of the subject may then be reconstructed from the zero-padded k-space using, for example an inverse Fast Fourier Transform (FFT). In some embodiments, the MR image 202 of the subject may be a low (or limited) spatial resolution image. Advantageously, the above-described acquisition scheme for the MR image 202 may enable data collection without the need to modify the pulse sequence used for the data acquisition and may minimize the impact of eddy currents.

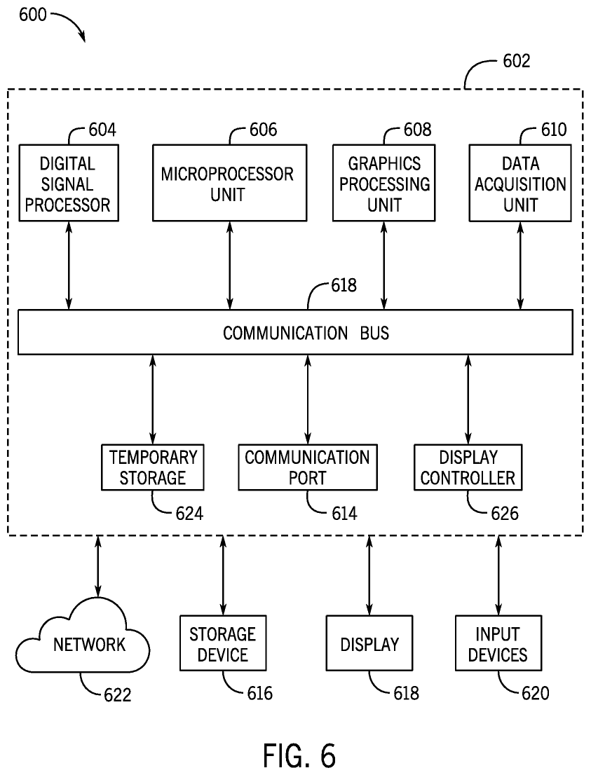

In some embodiments, the MR image 202 of the subject (e.g., a low resolution MR image) may be retrieved from data storage (or memory) 216 of system 200, data storage of the MRI system 100 shown in FIG. 1 or data storage of other computer systems (e.g., storage device 616 of computer system 600 shown in FIG. 6. In some embodiments, the MR image 202 of the subject may be acquired in real time (e.g., in an inline implementation of system 200 with an MRI system) from a subject using an MM system. For example, MR data 212 can be acquired from a subject using a pulse sequence performed on the MRI system. Known MM pulse sequences may be used to acquire MR data. For example, in some embodiments, a pulse sequence configured for cardiac MR imaging (e.g. a cine bSSFP sequence or a 3D LGE sequence) can be used to acquire MR data 212 or a pulse sequence configured for quantitative MR imaging can be used to acquire MR data 212. In some embodiments, a cardiac MRI cine sequence may be, for example, an ECG-segmented cine, a real time cine, or a real time cine with physiological stress. In addition, as discussed above, the MR data 212 may be undersampled (or accelerated) MR data that may be undersampled using either a uniform or non-uniform undersampling scheme. The acquired MR data 212 may be stored in, for example, data storage 216 of system 200, data storage of an MRI system (e.g., MM system 100 shown in FIG. 1), or data storage of other computer systems (e.g., storage device 616 of computer system 600 shown in FIG. 6). The acquired MR data 212 may then be reconstructed into the MR image 202 (e.g., a low resolution MR image) using known reconstruction methods. For example, image reconstruction module 214 may be configured to generate or reconstruct the low resolution MR image 202 of the subject from the acquired MR data 212. As discussed above, in some embodiments, an acceleration technique may be used to estimate (or interpolate) missing k-space lines in the central region of k-space, for example, a parallel imaging technique (e.g., GRAPPA or SENSE) for uniform undersampling schemes and a compressed sensing technique for non-uniform undersampling schemes. In some embodiments, the reconstructed central region of k-space may then be zero-padded (e.g., an out region of k-space) to create a zero-padded k-space. The MR image 202 of the subject may then be reconstructed from the zero-padded k-space using, for example an inverse Fast Fourier Transform (FFT). The MR image 202 (e.g., a low spatial resolution MR image) generated by image reconstruction module 214 may be stored in, for example, data storage 216 of system 200, data storage of an MRI system (e.g., MRI system 100 shown in FIG. 1), or data storage of other computer systems (e.g., storage device 616 of computer system 600 shown in FIG. 6).

The MR image 202 of the subject (e.g., a low resolution image) may be provided as an input to the generator network 204 of the trained image sharpness neural network 204. In some embodiments, the image sharpness neural network 204 may be configured to generate an output 210 including an enhanced resolution MR image of the subject. For example, using the input MR image 202, the image sharpness neural network 204 may be configured to generate an enhanced resolution MR image 210 of the subject with, for example, improved or high resolution (e.g., spatial resolution), increased (or improved) sharpness, and reduced artifacts. In some embodiments, the image sharpness neural network 204 may be used to enhance the spatial resolution of a low resolution MR image 202 reconstructed using partially acquired phase encoding lines in k-space. In some embodiments, the enhanced resolution MR image 210 may be an accelerated cardiac MR image such as, for example, a cine or LGE image. In an inline implementation, the image sharpness neural network 204 may receive the input MR image 202 from an MM system (e.g., MRI system 100 shown in FIG. 2) in real time and generate the enhanced resolution MR image 210 without additional user interaction.

In some embodiments, image sharpness neural network 204 may be a deep learning neural network. In some embodiments, the image sharpness neural network may be implemented using a modified enhanced super-resolution generative adversarial neural network (mESRGAN) model. Image sharpness neural network 204 may be a trained generative adversarial neural network and may include a generator network 206 and a discriminator network 208. As discussed further below, the discriminator network 208 and a training dataset 222 (both shown with dashed lines) may be used in a training process for image sharpness neural network 204 to train the generator network 206. Generator network 206 may be configured to receive the input MR image 202 (e.g., a low resolution MR image) and to generate the enhanced resolution MR image 210 with increased sharpness. For example, in some embodiments, the generator network 206 may be configured to enhance the spatial resolution along the phase encode direction. In addition, the generator network 206 may be configured to generate an enhanced resolution MR image 210 with the same or larger matrix size as the input MR image 202. For example, in some embodiments, the generator network 206 may be designed without an upsampling layer to generate an output image 210 with the same or larger matrix size as the input image 202.

Image sharpness neural network 204 may be configured to utilize a number of loss functions for a training process including a pixel loss function, a VGG loss function (e.g., perceptual loss), and a relativistic GAN loss function. In addition, image sharpness neural network 204 advantageously includes an additional L₁ Fast Fourier Transform loss function to, for example, provide constraints in the spatial frequency domain and to consider spatial frequency domain information. In some embodiments, the total loss function for the training process may be denoted as:

L_{Total}=w_{Pixel}L_{Pixel}+w_{VGG}L_{VGG}+w_{FFT}L_{FFT}+w_{GAN}L_{GAN} (3)

where wₚᵢₓₑₗ=0.01 w_{FFT}=0.01, w_{VGG}=1, and w_{GAN}=0.005.

Pixel loss can measure the difference between two images in the pixel domain. In some embodiments, the pixel loss function may be defined as:

L_{Pixel}=|l_{Enh}−l_{Ori}|² (4)

where l_{Enh} is an output image of generator network 206 (i.e. a generator network reconstructed image) and lₒᵣᵢ is an original spatial resolution image (i.e., a high resolution reference image). Perceptual loss can provide a comparison in the feature representation domain. In some embodiments, the VGG loss function may be defined as:

L_{VGG}=|VGG(l_{Enh})−VGG(lₒᵣᵢ)|² (5)

where VGG(·) is a function that maps from an image to a feature representation using, for example, a pre-trained VGG-19 network. The VGG loss function can provide the constraints in the perceptual domain.

The relativistic average GAN loss function can contain information about the reference image (i.e., used during training of the image sharpness neural network 204) as well as the output of the generator 206 (i.e., the reconstructed image) during training. Therefore, during training, the generator network 206 can be updated using the gradients of both the reconstructed image and the reference image through the relativistic average GAN loss. This can prevent gradient vanishing and can help to train sharp edges and texture. In some embodiments, the relativistic average GAN loss functions may be separately defined for the discriminator network 208 and the generator network 206. In the discriminator network 208, the relativistic average GAN loss, L_{RaGAN}^{Dis} may be defined as:

L_{RaGAN}^{Dis}=− [symbol] _{I}_{ₒᵣᵢ}[log(σ(C₁))]− [symbol] _{I}_{_{Enh}}[log(1−σ(C₂))] (6)

where C₁=C(Iₒᵣᵢ)− [symbol] [C(I_{Enh})] and C₂=C(I_{Enh})− [symbol] _{I}_{ₒᵣᵢ} [C(Iₒᵣᵢ)]. On the other hand, the relativistic average GAN loss of generator 206, L_{RaGAN}^{Gen}, may be defined as:

L_{RaGAN}^{Gen}=− [symbol] _{I}_{ₒᵣᵢ}[log(1−σ(C₃))]− [symbol] _{I}_{_{Enh}}[log(σ(C⁴))] (7)

where C₃=C(Iₒᵣᵢ)− [symbol] _{I}_{_{Enh}}[C(I_{Enh})] and C₄=C(I_{Enh})− [symbol] _{I}_{ₒᵣᵢ}C(Iₒᵣᵢ). Here, σ(·) is a sigmoid function, C(·) is the non-transformed output of the discriminator network and the [symbol] (·) represents the expectation on the distribution. The relativistic average GAN loss of generator 206, L_{RaGAN}^{Gen}, may contain terms for an original resolution image (or high resolution reference image) and an output image of generator network 206 (or reconstructed image); therefore, the generator 206 may be updated using the gradient from both images. During training of the generator network 206, this may help prevent gradient vanishing and learn sharper edge and texture. The discriminator network 208 may be trained using only relativistic average GAN loss, LR_{aGAN}^{Dis}.

The L₁ FFT loss function can provide constraints in the spatial frequency domain, which can allow the image sharpness neural network 204 (i.e. generator network 206) to learn, for example, to restore information of the omitted phase encoding lines in signal acquisition. In some embodiments, the L₁ Fast Fourier Transform loss function may be defined as:

L_{FFT}=|_{FFT}(l_{Enh})−FFT(lₒᵣᵢ)| (8)

where FFT(·) is a Fourier transformation that maps from an image to a spatial frequency domain. As mentioned, the L₁ Fast Fourier Transform loss function can provide the constraints in the frequency domain, enabling the generator network 206 to learn skipped phase-encoding lines.

The generated enhanced resolution MR image with increased sharpness 210 output by the trained image sharpness neural network 204 (e.g., by trained generator network 206) may be displayed on a display 218 (e.g., displays 104, 136 and/or 144 of MRI system 100 shown in FIG. 1, or display 618 of the computer system 600 shown in FIG. 6). In addition, the input low resolution MR image 202 may also be displayed on display 218. As discussed above, in an inline implementation of system 200 including GAN 204, both the input low resolution MR image 202 and the output enhanced resolution MR image 210 may advantageously be available (e.g., displayed) immediately to a user allowing the user to review the images in real time to, for example, determine if a follow up scan is needed. The enhanced resolution MR image 210 and the low resolution MR image 202 may also be stored in data storage 218 (e.g., data storage of the MRI system 100 shown in FIG. 1 or data storage 616 of computer system 600 shown in FIG. 6).

As mentioned above, the discriminator network 208 (shown with dashed lines) of image sharpness neural network 204 and a training dataset 222 (shown with dashed lines) may be used in a training process for image sharpness neural network 204 to train the generator network 206. The discriminator network 208 may be configured to distinguish inputs composed of the image sharpness neural network 204 enhanced resolution images (reconstructed images), for example, generated by the generator network 206 and original spatial resolution images (or high resolution references images) to provide data distribution information to generator network 206 during training of image sharpness neural network 204. For example, during training the discriminator network 208 may be configured to classify (e.g., estimate a probability) whether an image generated by the generator network 206 (a reconstructed image) from an input image is an actual reference image or a reconstructed image. The image sharpness neural network 204 may be trained using known methods including, but not limited to, a supervised approach.

In some embodiments, the training dataset 222 may include pairs of low spatial resolution MR images and original (i.e., high resolution) spatial resolution MR images (or synthesized low resolution images and reference images, respectively) that may be generated using inverse FFT. In some embodiments, image sharpness neural network 204 may be trained using image patches generated from the training dataset 222 by using, for example, random cropping. In some embodiments, the training dataset 222 includes MR images acquired using one or more different MR acquisitions (e.g., cine and LGE). In some embodiments, the training dataset 222 may be generated.by first reconstructing retrospectively collected multi-coil complex-valued and uniformly undersampled k-space data using, for example, a known parallel imaging technique (e.g., GRAPPA). The inverse Fast Fourier Transform (FFT) may be performed to convert the parallel imaging-reconstructed k-space of each coil into the image domain. In some embodiments, the original spatial resolution (or high resolution) reference image may then be generated using, for example, a sum-of-squares coil combination. To create corresponding low spatial resolution images paired with original resolution images, in some embodiments the fully sampled k-space or under sampled k-space reconstructed using parallel imaging (e.g. GRAPPA) or compressed sensing (CS) of each coil may be divided into the inner and outer k-space by randomly selecting a threshold percentage, for example, 25-50%, in the phase-encoding (k_{y}) direction. While maintaining the resolution in the readout direction (kₓ), the outer k-space data may be discarded to synthesize low spatial resolution acquisition. The synthesized k-space is converted to a low spatial resolution image through an inverse FFT. Afterward, a low spatial resolution image may be generated through a sum-of-squares coil combination.

In some embodiments, the image sharpness neural network 202 and the image reconstruction module 214 may be implemented on one or more processors (or processor devices) of a computer system such as, for example, any general-purpose computing system or device, such as a personal computer, workstation, cellular phone, smartphone, laptop, tablet, or the like. As such, the computer system may include any suitable hardware and components designed or capable of carrying out a variety of processing and control tasks, including steps for implementing the imaging reconstruction module 214, receiving an MR image 202 of a subject (e.g., a low resolution MR image), implementing the image sharpness neural network 204, providing the enhanced resolution MR image 210 and the input MR image 202 to a display 218 or storing the enhanced resolution MR image 210 and the input MR image 202 in data storage 220. For example, the computer system may include a programmable processor or combination of programmable processors, such as central processing units (CPUs), graphics processing units (GPUs), and the like. In some implementations, the one or more processor of the computer system may be configured to execute instructions stored in a non-transitory computer readable-media. In this regard, the computer system may be any device or system designed to integrate a variety of software, hardware, capabilities and functionalities. Alternatively, and by way of particular configurations and programming, the computer system may be a special-purpose system or device. For instance, such special-purpose system or device may include one or more dedicated processing units or modules that may be configured (e.g., hardwired, or pre-programmed) to carry out steps, in accordance with aspects of the present disclosure.

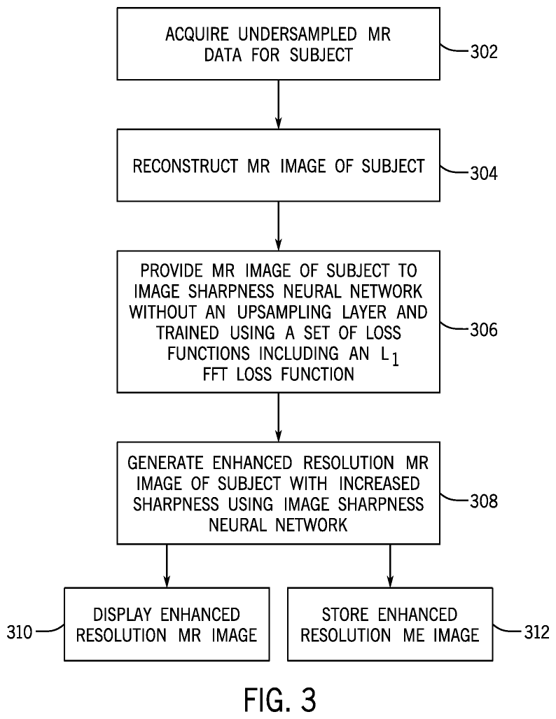

FIG. 3 illustrates a method for generating a magnetic resonance image using an image sharpness neural network in accordance with an embodiment. The process illustrated in FIG. 3 is described below as being carried out by the system 200 for generating a magnetic resonance image as illustrated in FIG. 2. Although the blocks of the process are illustrated in a particular order, in some embodiments, one or more blocks may be executed in a different order than illustrated in FIG. 3 or may be bypassed.

At block 302, MR data 212 may be acquired from a subject using an MRI system such as, for example, MM system 100 shown in FIG. 1. In some embodiments, the MR data 212 may be acquired using known MR imaging acquisition techniques, for example, cardiac MR imaging acquisition techniques including, but not limited to, cine and LGE or quantitative MR imaging acquisition techniques including, but not limited to T1, T2, and T2*. In some embodiments, a cardiac MRI cine sequence may be, for example, an ECG-segmented cine, a real time cine, or a real time cine with physiological stress. In addition, as discussed above, the MR data 212 may be undersampled (or accelerated) MR data that may be undersampled using either a uniform or non-uniform undersampling scheme. In some embodiments, the undersampled k-space data is collected or acquired from the central (or inner) region of k-space. In some embodiments, the undersampled k-space data can include a reduced (e.g., partially acquired) number of phase encode lines. In some embodiments, the phase encode lines may be acquired only in the central region of k-space (i.e., outer k-space lines are not collected). The acquired MR data 212 may be stored in, for example, data storage 216 of system 200, data storage of an MRI system (e.g., MRI system 100 shown in FIG. 1), or data storage of other computer systems (e.g., storage device 616 of computer system 600 shown in FIG. 6).

At block 304, an MR image 202 of the subject may be reconstructed (e.g., using image reconstruction module 214) from the acquired MR data 212 using known reconstruction methods. In some embodiments, the MR image 202 of the subject is a low resolution MR image. As discussed above, in some embodiments, an acceleration technique may be used to estimate (or interpolate) missing k-space lines in the central region of k-space, for example, a parallel imaging technique (e.g., GRAPPA or SENSE) for uniform undersampling schemes and a compressed sensing technique for non-uniform undersampling schemes. In some embodiments, the reconstructed central region of k-space may then be zero-padded (e.g., an out region of k-space) to create a zero-padded k-space. The MR image 202 of the subject may then be reconstructed from the zero-padded k-space using, for example an inverse Fast Fourier Transform (FFT). The generated MR image 202 (e.g., a low spatial resolution MR image) may be stored in, for example, data storage 216 of system 200, data storage of an MRI system (e.g., MRI system 100 shown in FIG. 1), or data storage of other computer systems (e.g., storage device 616 of computer system 600 shown in FIG. 6).

At block 306, the MR image 202 (e.g., a low resolution MR image) may be provided to a trained image sharpness neural network 204 configured to generate an output 210 including an enhanced resolution MR image 210 of the subject with increased sharpness based on the MR image 202 input to the image sharpness neural network 204. In some embodiments, the image sharpness neural network 204 does not include an upsampling layer and may be trained using a set of loss functions including an L₁ Fast Fourier Transform loss function. At block 308, the image sharpness neural network 204 may be used to generate an enhanced resolution (e.g., high resolution) MR image 210 of the subject. For example, using the input MR image 202 (e.g., a low resolution MR image), the image sharpness neural network 204 may be configured to generate an enhanced resolution MR image 210 of the subject with, for example, improved or high resolution (e.g., spatial resolution), improved (or increased) sharpness, and reduced artifacts. In addition, the image sharpness neural network 204 may be configured to advantageously generate an enhanced resolution MR image 210 with the same or larger matrix size as the input MR image 202. For example, in some embodiments, a generator network 206 of the image sharpness neural network 204 may be designed without an upsampling layer to generate an output image 210 with the same matrix size as the input image 202. As discussed above, image sharpness neural network 204 may also advantageously include an L₁ Fast Fourier Transform loss function to, for example, provide constraints in the spatial frequency domain and to consider spatial frequency domain information. In some embodiments, the L₁ Fast Fourier Transform loss function can enable the generator network 206 of the image sharpness neural network 204 to learn skipped phase-encoding lines.

At block 310, the generated enhanced resolution MR image 210 with increased sharpness and/or the input MR image 202 can be displayed on a display 218 (e.g., displays 104, 136 and/or 144 of MRI system 100 shown in FIG. 1, or display 618 of the computer system 600 shown in FIG. 6). At block 312, the generated enhanced resolution MR image 210 with increased sharpness and/or the input MR image 202 may also be stored in data storage 220 (e.g., data storage of the MRI system 100 shown in FIG. 1 or other computer system).

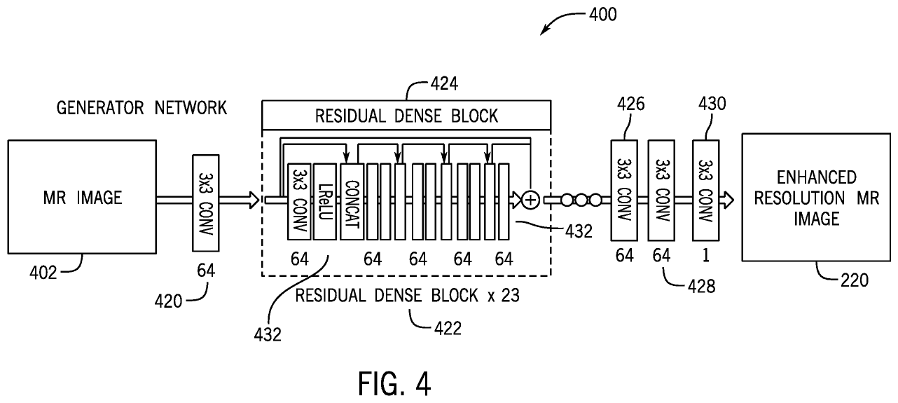

As mentioned above, in some embodiments the image sharpness neural network 204 (shown in FIG. 2) can include a generator network 206 and a discriminator network 208. The discriminator network may be used during training of the generator network 206. FIG. 4 illustrates a generator network architecture for the image sharpness neural network of FIG. 2 in accordance with an embodiment. As discussed above with respect to FIG. 3, a trained generator network 400 of the image sharpness neural network 204 may be configured to receive an MR image 402 (e.g., a low resolution MR image such as a low spatial resolution MR image) of a subject as input and to generate an output of an enhanced MR resolution image 410 that, for example, improves resolution, improves sharpness, and reduces artifacts. Advantageously, in some embodiments, the enhanced resolution MR image 410 output has the same or larger size (e.g., matrix size) as the input MR image 402. In some embodiments, the generator network 400 may be designed without an upsampling layer to generate an output image 410 with the same size as the input image 402. It can be advantageous to generate an output enhanced resolution MR image 410 that is the same size as the input MR image 402 because, for example, resizing in the image reconstruction stage can cause a delay in data communication in an inline implementation, and, unlike natural images, resolution adjustment in MR imaging is determined by data acquisition in k-space. The generator network 400 can include four two-dimensional (2D) convolutional layers 420, 426, 428, and 430. The generator network 400 architecture illustrated in FIG. 4 also includes simplified basic blocks. In some embodiments, the basic block of the generator network 400 may be selected as a residual dense block 424 (or residual dense connection block) that may be configured to densely connect and concatenate features. In the example generator network 400 architecture, a number 422 of residual dense blocks 424 may be used, for example, twenty-three residual dense blocks. By using the simplified basic blocks, e.g., a residual dense block 424, the total number of parameters of the generator network 400 may be reduced in order to reduce computational complexity and allow training using limited training data. In some embodiments, this memory gain can enable the inclusion of more data to train image sharpness neural network 204 efficiently. In the architecture illustrated in FIG. 4, 2D convolution layers 420, 426, 428, and 430 in the generator network 400 may include, for example, 64 filters. In some embodiments, the last 2D convolution layer 430 may include only one filter for one channel-image output. In the example architecture illustrated in FIG. 3, 2D convolution layers (420, 326, 428 and 430) with kernel size=3×3 were used.

As mentioned, the generator network 400 may be configured to generate an enhanced resolution MR image 410 with increased sharpness from an acquired MR image 402 of the subject (e.g., a low resolution MR image) input to the generator network 400. In the architecture illustrated in FIG. 4, first a 2D convolution 420 may be applied to the input low resolution MR image 402, then the plurality (e.g., 23) of dense residual blocks 424 may be applied. In some embodiments, each residual dense block 424 may include five sub-blocks 432 that may include, for example, a 2D convolution layer and a Leaky ReLU function. Residual connections between the sub-blocks 432 may be created by concatenating feature maps. Next, three 2D convolution layers 426, 428, 430 may be applied. As mentioned, the last 2D convolution layer 430 may include only one kernel for a one-channel output.

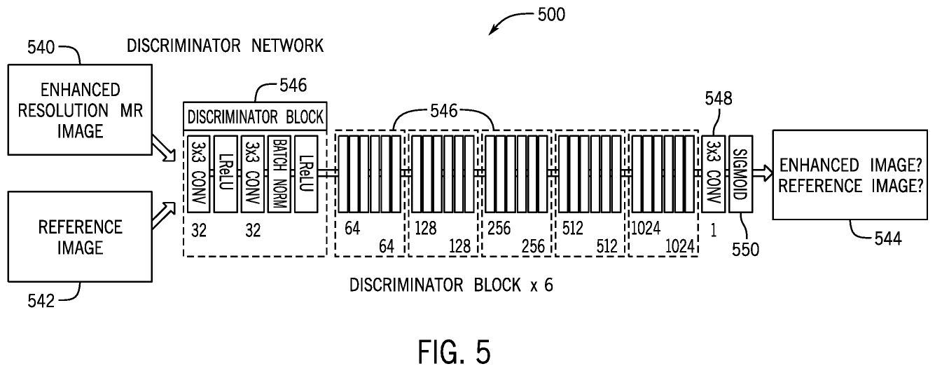

FIG. 5 illustrates a discriminator network architecture for the image sharpness neural network of FIG. 2 in accordance with an embodiment. As discussed above with respect to FIG. 2, the discriminator network 500 may be used during training of the image sharpness neural network 204 and may be configured to distinguish an enhanced resolution MR image 540 (or reconstructed image) generated by the generator network (e.g., generator network 400) from an original resolution (e.g., spatial resolution) image or reference image 542. For example, the discriminator network 500 may provide an estimate 544 whether the input image 540 is a resolution enhanced image reconstructed by generator 400 or a reference image. In some embodiments, to have a better data distribution representation and dynamic input size, the discriminator network 500 may utilize convolution layers rather than fully connected layers. The discriminator network 500 architecture illustrated in FIG. 5 is configured as a fully convolutional neural network consisting of 6 discriminator blocks 546 and one 2D convolutional layer 548. The example architecture of discriminator network 500 can allow for learning a better representation of data with dynamic input sizes. In some embodiments, each discriminator block 546 may consist of two 2D convolution layers, batch normalizations, and Leaky ReLU functions. In some embodiments, the filters in the 2D convolution layer of each discriminator block 546 may be 32, 64, 128, 256, 512, and 1024, respectively. Therefore, the feature's width and height may become halved, and the number of channels may be doubled for each step of the discriminator block 546. This can transform spatial features into deep channel dimensions, enabling higher-level data feature representations. In some embodiments, the last 2D convolution layer 548 may have only one filter for one channel output before a sigmoid function 550. In some embodiments, the 2D convolution layers may have a kernel size of 3×3.

FIG. 6 is a block diagram of an example computer system in accordance with an embodiment. Computer system 600 may be used to implement the systems and methods described herein. In some embodiments, the computer system 600 may be a workstation, a notebook computer, a tablet device, a mobile device, a multimedia device, a network server, a mainframe, one or more controllers, one or more microcontrollers, or any other general-purpose or application-specific computing device. The computer system 600 may operate autonomously or semi-autonomously, or may read executable software instructions from the memory or storage device 616 or a computer-readable medium (e.g., a hard drive, a CD-ROM, flash memory), or may receive instructions via the input device 620 from a user, or any other source logically connected to a computer or device, such as another networked computer or server. Thus, in some embodiments, the computer system 600 can also include any suitable device for reading computer-readable storage media.

Data, such as data acquired with an imaging system (e.g., a magnetic resonance imaging (MRI) system) may be provided to the computer system 600 from a data storage device 616, and these data are received in a processing unit 602. In some embodiment, the processing unit 602 includes one or more processors. For example, the processing unit 602 may include one or more of a digital signal processor (DSP) 604, a microprocessor unit (MPU) 606, and a graphics processing unit (GPU) 608. The processing unit 602 also includes a data acquisition unit 610 that is configured to electronically receive data to be processed. The DSP 604, MPU 606, GPU 608, and data acquisition unit 610 are all coupled to a communication bus 612. The communication bus 612 may be, for example, a group of wires, or a hardware used for switching data between the peripherals or between any components in the processing unit 602.

The processing unit 602 may also include a communication port 614 in electronic communication with other devices, which may include a storage device 616, a display 618, and one or more input devices 620. Examples of an input device 620 include, but are not limited to, a keyboard, a mouse, and a touch screen through which a user can provide an input. The storage device 616 may be configured to store data, which may include data such as, for example, acquired MR data, MR images, enhanced resolution MR images, whether these data are provided to, or processed by, the processing unit 602. The display 618 may be used to display images and other information, such as magnetic resonance images, patient health data, and so on.

The processing unit 602 can also be in electronic communication with a network 622 to transmit and receive data and other information. The communication port 614 can also be coupled to the processing unit 602 through a switched central resource, for example the communication bus 612. The processing unit can also include temporary storage 624 and a display controller 626. The temporary storage 624 is configured to store temporary information. For example, the temporary storage 624 can be a random access memory.

Computer-executable instructions for generating a magnetic resonance image using an image sharpness neural network according to the above-described methods may be stored on a form of computer readable media. Computer readable media includes volatile and nonvolatile, removable, and non-removable media implemented in any method or technology for storage of information such as computer readable instructions, data structures, program modules or other data. Computer readable media includes, but is not limited to, random access memory (RAM), read-only memory (ROM), electrically erasable programmable ROM (EEPROM), flash memory or other memory technology, compact disk ROM (CD-ROM), digital volatile disks (DVD) or other optical storage, magnetic cassettes, magnetic tape, magnetic disk storage or other magnetic storage devices, or any other medium which can be used to store the desired instructions and which may be accessed by a system (e.g., a computer), including by internet or other computer network form of access

The present invention has been described in terms of one or more preferred embodiments, and it should be appreciated that many equivalents, alternatives, variations, and modifications, aside from those expressly stated, are possible and within the scope of the invention.

1. A method for generating a magnetic resonance (MR) image of a subject, the method comprising:
receiving an MR image of the subject reconstructed from undersampled MR data of the subject;
providing the MR image of the subject to an image sharpness neural network without an upsampling layer, the image sharpness neural network trained using a set of loss functions including an L₁ Fast Fourier Transform (FFT) loss function; and
generating an enhanced resolution MR image of the subject with increased sharpness based on the MR image of the subject using the image sharpness neural network.

2. The method according to claim 1, wherein the MR image of the subject is reconstructed from undersampled MR data from a central region of k-space.

3. The method according to claim 1, wherein the image sharpness neural network is a deep learning neural network comprising a generator network comprising two-dimensional (2D) convolution layers and residual dense blocks.

4. The method according to claim 3, wherein the generator network includes four 2D convolution layers and twenty-three residual dense blocks.

5. The method according to claim 4, wherein at least three of the four 2D convolution layers includes a plurality of filters.

6. The method according to claim 5, wherein the plurality of filters for each of the at least three 2D convolution layers includes sixty four filters.

7. The method according to claim 4, wherein at least one of the four 2D convolution layers includes one filter.

8. The method according to claim 3, wherein the image sharpness neural network further comprises a discriminator network comprising a 2D convolution layer and six discriminator blocks.

9. The method according to claim 8, wherein the discriminator network is a fully convolutional neural network.

10. The method according to claim 1, wherein the set of loss functions further includes pixel loss function, a perceptual loss function, and a relativistic average generative adversarial network (GAN) loss function.

11. The method according to claim 1, wherein the image sharpness neural network is trained using a training dataset comprising pairs of training images, wherein each pair comprises a training high resolution reference image and corresponding training low resolution image.

12. The method according to claim 11, wherein the training high resolution reference image and the training low resolution image in each pair are reconstructed from undersampled MR data.

13. The method according to claim 12, wherein the training low resolution image in each pair is reconstructed by undersampling k-space in a phase-encoding direction.

14. The method according to claim 13, wherein undersampling k-space in a phase-encoding direction includes retrospectively undersampling phase encode lines of k-space.

15. The method according to claim 1, further comprising displaying the enhanced resolution MR image of the subject with increased sharpness.

16. A system for generating a magnetic resonance (MR) image of a subject, the system comprising:
an input for receiving an MR image of the subject reconstructed from undersampled MR data of the subject; and
an image sharpness neural network without an upsampling layer and coupled to the input, the image sharpness neural network trained using a set of loss functions including an L₁ Fast Fourier Transform (FFT) loss function, the image sharpness neural network configured to generate an enhanced resolution MR image of the subject with increased sharpness based on the MR image of the subject.

17. The system according to claim 16, further comprising a display coupled to the image sharpness neural network and configured to display the enhanced resolution MR image of the subject with increased sharpness.

18. The system according to claim 16, wherein the image sharpness neural network is a deep learning neural network comprising a generator network comprising two-dimensional (2D) convolution layers and residual dense blocks.

19. The system according to claim 18, wherein the generator network includes four 2D convolution layers and twenty-three residual dense blocks.

20. The system according to claim 19, wherein at least three of the four 2D convolution layers includes a plurality of filters.

21. The system according to claim 20, wherein the plurality of filters for each of the at least three convolution layers includes sixty four filters.

22. The system according to claim 19, wherein the at least one of the four 2D convolution layers includes one filter.

23. The system according to claim 18, wherein the image sharpness neural network further comprises a discriminator network comprising a 2D convolution layer and six discriminator blocks.

24. The system according to claim 23, wherein the discriminator network is a fully convolutional neural network.

25. The system according to claim 16, wherein the set of loss functions further includes a pixel loss function, a perceptual loss function, and a relativistic adversarial network (GAN) loss function.

26. The system according to claim 16, wherein the image sharpness network is trained using a training dataset comprising pairs of training images, wherein each pair comprises a high resolution reference image and a corresponding training low resolution image.

27. The system according to claim 26, wherein the training high resolution reference image and the training low resolution image in each pair are reconstructed from undersampled MR data.

28. The system according to claim 27, wherein the training low resolution image in each pair is reconstructed by undersampling k-space in a phase-encoding direction.

29. The system according to claim 28, wherein undersampling k-space in a phase-encoding direction includes retrospectively undersampling phase encode lines of k-space.
